(19) United States
(12) Patent Application Publication
(10) Pub. No.: US 2014/0306311 A1
(43) Pub. Date: Oct. 16, 2014

(54) SOLID-STATE IMAGING ELEMENT

(71) Applicant: Sharp Kabushiki Kaisha, Osaka (JP)

(72) Inventor: Daisuke Funao, Osaka (JP)

(21) Appl. No.: 14/361,899

(22) PCT Filed: Nov. 8, 2012
(86) PCT No.: PCT/JP2012/078979

§ 371 Date: May 30, 2014

(30) Foreign Application Priority Data
Dec. 1, 2011 (JP) 2011-263892

(51) Int. Cl. H01L 27/146

(52) U.S. Cl. CPC H01L 27/14601
USPC 257/432

(57) ABSTRACT

Provided is a solid-state imaging element for effectively reducing a dark current. The solid-state imaging element includes a substrate 10 formed of semiconductor and having a plurality of pixel regions, a plurality of storage units 11 arranged in the respective pixel regions in the substrate 10, formed of semiconductor having a conductivity type opposite to the substrate 10, and configured to store a charge having a first polarity and generated by photoelectric conversion, and a fixed charge layer 14a provided above at least one substrate surface 102 and having a first fixed charge E. A density of accumulation charges h having a polarity opposite to the first fixed charge E in the substrate surface 102 varies based on an arrangement of the pixel regions or an arrangement of the storage units, with respect to a direction parallel to the substrate surface 102.

### TECHNICAL FIELD

The present invention relates to a solid-state imaging element which is typified by a CMOS (Complementary Metal Oxide Semiconductor) imaging sensor or a CCD (Charge Coupled Device) imaging sensor.

### BACKGROUND ART

Recently, the solid-state imaging element such as the CCD imaging sensor or the CMOS imaging sensor is mounted in an imaging device such as a digital video camera or digital still camera, or various electronic devices each having an imaging function such as a camera cell phone. The solid-state imaging element photoelectrically converts irradiated light to generate charges, and amplifies a potential of those charges to generate image data.

As for the solid-state imaging element, one of the most important issues is to reduce a noise. Especially, a dark current which is one of the causes of the noise needs to be reduced. The dark current is generated when the charge is supplied to a storage unit, due to a defect of a substrate having a light receiving unit (photodiode), and an amount of the noise caused by the dark current is increased as a storage time of the charges lengthens in the solid-state imaging element, and as a temperature rises in the solid-state imaging element.

As the defect to cause the dark current, there are various defects such as an interface state (surface level) caused by a crystal defect or dangling bond, and a defect caused by heavy-metal pollution, and these are mainly formed in a substrate surface. That is, a generation source of the dark current is mostly the substrate surface.

Thus, for example, Patent Document 1 discloses a solid-state imaging element in which a p-type region is provided around an n-type storage unit for storing electrons generated by photoelectric conversion. This solid-state imaging element is configured such that the storage unit is formed by implanting an n-type impurity into the substrate, the p-type region is provided by implanting a p-type impurity into the substrate so that the storage unit is away from a substrate surface.

However, according to this solid-state imaging element, when a p-type implanted amount or implanted area is increased, characteristics of the photoelectric conversion and electric characteristics such as a saturation charge amount are deteriorated. Furthermore, when a heat treatment is performed to activate the p-type impurity at high temperature, an element structure could be damaged or altered due to the heat treatment. More specifically, a dopant which has been implanted into the substrate prior to the heat treatment is unintentionally diffused in the high-temperature heat treatment, which deteriorates the characteristics of the photoelectric conversion and the electric characteristics such as the saturation charge amount. In addition, as for a back side irradiation type solid-state imaging element, at the time of p-type implantation in the substrate, an element and a wiring are formed on a surface of the substrate, so that a heat treatment after the implantation has many restrictions.

Thus, for example, Patent Documents 2 and 3 disclose a solid-state imaging element in which a fixed charge layer having a negative fixed charge is provided on a surface of a substrate having a light receiving unit. According to this solid-state imaging element, since the fixed charge layer is provided, a hole is accumulated in the substrate surface, and this hole is recombined with an electron making a dark current, so that the electron is prevented from moving to a storage unit, and the dark current is reduced.

### PRIOR ART DOCUMENT

### Patent Document

Patent Document 1: JP 2000-299453 A
Patent Document 2: JP 2008-306154 A
Patent Document 3: JP 2010-239155 A

### DISCLOSURE OF THE INVENTION

### Problems to be Solved by the Invention

In order to effectively move and store the charge generated by photoelectric conversion into the storage unit, a lifetime of the charge in the substrate is better to be long. For example, when the substrate is composed of silicon, a sufficient lifetime can be ensured. However, a lifetime of the charge making the dark current is also long. In this case, even in the case of the solid-state imaging element disclosed in Patent Documents 2 and 3, the electron making the dark current could reach the storage unit before that electron is recombined with the hole accumulated in the substrate surface. That is, the dark current could not be sufficiently reduced.

Thus, an object of the present invention is to provide a solid-state imaging element capable of effectively reducing the dark current.

### Means for Solving the Problem

To achieve the object described above, the present invention provides a solid-state imaging element including:

a substrate formed of semiconductor and having a plurality of pixel regions;

a plurality of storage units, each of which being arranged in the substrate with respect to each of the pixel regions, formed of semiconductor having a conductivity type opposite to the substrate, and configured to store a charge having a first polarity and generated by photoelectric conversion; and

a fixed charge layer provided above at least one substrate surface and having a first fixed charge, wherein

a density of accumulation charges provided in the substrate surface and having a polarity opposite to the first fixed charge varies based on an arrangement of the pixel regions or an arrangement of the storage units, with respect to a direction parallel to the substrate surface.

According to this solid-state imaging element, an electric field is generated with respect to the direction parallel to the substrate surface, based on a distribution of the density of the accumulation charges. Therefore, charges making the dark current generated due to a defect of the substrate surface move not only toward the storage unit, but also along the substrate surface, so that the charge takes a longer route and a longer time to reach the storage unit, compared to a case where the density of the accumulation charges is uniform with respect to the direction parallel to the second substrate surface. Therefore, it is possible to improve the probability that the charge disappears due to recombination before the charge reaches the storage unit.

In addition, the conductivity type of the semiconductor composing the substrate is a p type or n type. For example, when the semiconductor composing the substrate has the p type, the semiconductor composing the storage unit has the n type, and when the semiconductor composing the substrate has the n type, the semiconductor composing the storage unit has the p type. In addition, the “conductivity type of the semiconductor composing the substrate” means a conductivity type shown in a region having an element structure in the substrate, so that it includes not only a conductivity type shown in the whole substrate, but also a conductivity type shown in a well of the substrate, as a matter of course.

Further, in the solid-state imaging element having the above characteristics, preferably, a polarity of the first fixed charge is the first polarity, and a polarity of the accumulation charge is a second polarity opposite to the first polarity.

According to this solid-state imaging element, the charge having the first polarity and making the dark current moves in the accumulation charges having the second polarity serving as the opposite polarity. Therefore, the charge making the dark current can effectively disappear due to the recombination.

Furthermore, in the case where the first polarity is negative, each of the charge stored in the storage unit and the charge making the dark current serves as the electron, and the accumulation charge serves as the hole. Furthermore, in the case where the first polarity is positive, each of the charge stored in the storage unit and the charge making the dark current serves as the hole, and the accumulation charge serves as the electron.

Further, in the solid-state imaging element having the above characteristics, the density of the accumulation charges in the substrate surface may become high in a region getting close to the storage unit, and may become low in a region getting away from the storage unit, with respect to the direction parallel to the substrate surface. In addition, in the solid-state imaging element having the above characteristics, the density of the accumulation charges in the substrate surface may become low in a region getting close to the storage unit, and may become high in a region getting away from the storage unit, with respect to the direction parallel to the substrate surface.

According to this solid-state imaging element, the charge making the dark current is likely to move so as to get away from the storage unit or get close to the storage unit after the charge is generated in the substrate surface, due to the electric field generated with respect to the direction parallel to the substrate surface, and then move toward the storage unit. That is, it is possible to lengthen the route and the time before the charge making the dark current reaches the storage unit.

In addition, when the charge generated by the photoelectric conversion moves so as to get close to the storage unit with respect to the direction parallel to the substrate surface, it is possible to improve the probability that the charge moves to the storage unit in which that charge is to be originally stored. Therefore, colors can be prevented from being mixed. In addition, only by forming the fixed charge layer above the substrate surface, it is not necessary to implant the impurity having the conductivity type opposite to the storage unit, so that it is not necessary to perform the heat treatment associated with the implantation of the impurity. Therefore, it is possible to prevent destruction of structure and deterioration of the characteristics due to the heat treatment.

Further, in the solid-state imaging element having the above characteristics, a density of the first fixed charges in a region close to the storage unit in the fixed charge layer bay be different from a density of the first fixed charges in a region away from the storage unit in the fixed charge layer, with respect to the direction parallel to the substrate surface. For example, since the charge density of the fixed charge layer depends on the heat treatment, a heat treatment method performed for the region close to the storage unit in the fixed charge layer may be differentiated from a heat treatment method performed for the region away from the storage unit in the fixed charge layer, with respect to the direction parallel to the second substrate surface. In addition, since the charge density of the fixed charge layer depends on the impurity to be added, an additive condition of the impurity in the region close to the storage unit in the fixed charge layer may be differentiated from an additive condition of the impurity in the region away from the storage unit in the fixed charge layer, with respect to the direction parallel to the substrate surface.

According to this solid-state imaging element, it is possible to provide a difference between a density of the accumulation charges in the region close to the storage unit in the substrate surface and a density of the accumulation charges in the region away from the storage unit in the substrate surface, with respect to the direction parallel to the substrate surface, based on the distribution of the density of the fixed charges in the fixed charge layer, so that the electric field can be generated in that direction.

Further, in the solid-state imaging element having the above characteristics, a film thickness of the region close to the storage unit in the fixed charge layer may be different from a film thickness of the region away from the storage unit in the fixed charge layer, with respect to the direction parallel to the substrate surface.

According to this solid-state imaging element, it is possible to provide the difference between the density of the accumulation charges in the region close to the storage unit in the substrate surface and the density of the accumulation charges in the region away from the storage unit in the substrate surface, with respect to the direction parallel to the substrate surface, based on a distribution of the film thickness of the fixed charge layer, so that the electric field can be generated in that direction.

Furthermore, as for the solid-state imaging element having the above characteristics, a material of at least one part in the region close to the storage unit in the fixed charge layer may be different from a material of at least one part in the region away from the storage unit in the fixed charge layer, with respect to the direction parallel to the substrate surface.

According to this solid-state imaging element, it is possible to provide the difference between the density of the accumulation charges in the region close to the storage unit in the substrate surface and the density of the accumulation charges in the region away from the storage unit in the substrate surface, with respect to the direction parallel to the substrate surface, based on a distribution of the material of the fixed charge layer, so that the electric field can be generated in that direction.

Furthermore, as for the solid-state imaging element having the above characteristics, the region close to the storage unit in the fixed charge layer or the region away from the storage unit in the fixed charge layer, with respect to the direction parallel to the substrate surface may have a second fixed charge having the second polarity.

According to this solid-state imaging element, the substrate surface has not only the accumulation charge having the first polarity, but also the accumulation charge having the second polarity. Therefore, a strong electric field can be generated with respect to the direction parallel to the substrate surface, compared to the electric field generated only due to the density difference of the accumulation charges having the first polarity.

Furthermore, as for the solid-state imaging element having the above characteristics, a distance between the region close to the storage unit in the fixed charge layer and the substrate surface may be different from a distance between the region away from the storage unit in the fixed charge layer and the substrate surface, with respect to the direction parallel to the substrate surface. For example, a base layer formed of insulator may be provided between the substrate surface and the fixed charge layer, in which a film thickness of a region close to the storage unit in the base layer may be different from a film thickness of a region away from the storage unit in the base layer, with respect to the direction parallel to the substrate surface.

According to this solid-state imaging element, it is possible to provide the difference between the density of the accumulation charges in the region close to the storage unit in the substrate surface and the density of the accumulation charges in the region away from the storage unit in the substrate surface, with respect to the direction parallel to the substrate surface, based on a distribution of the distance between the substrate surface and the fixed charge layer, so that the electric field can be generated in that direction.

Furthermore, as for the solid-state imaging element having the above characteristics, a barrier unit having a higher impurity concentration than a surrounding area is preferably formed in the region away from the storage unit in the substrate, with respect to the direction parallel to the substrate surface.

According to this solid-state imaging element, a potential barrier between the adjacent storage units can be clearly provided, so that it is possible to improve the probability that the charge generated by the photoelectric conversion moves to the storage unit in which the charge is originally to be stored. Therefore, colors can be prevented from being mixed.

Furthermore, as for the solid-state imaging element having the above characteristics, an attraction unit of semiconductor having the conductivity type opposite to the substrate may be formed in the barrier unit beside the substrate surface.

According to this solid-state imaging element, the charge making the dark current can be confined into the substrate surface. Therefore, it is possible to improve the probability that the charge making the dark current disappears due to recombination before the charge reaches the storage unit.

Furthermore, as for the solid-state imaging element having the above characteristics, an electrode layer may be further provided in the region close to the storage unit above the fixed charge layer, or the region away from the storage unit above the fixed charge layer, with respect to the direction parallel to the substrate surface,

in which a voltage having the same polarity as the first fixed charge is preferably applied to the electrode layer at least while the charge having the first polarity is stored in the storage unit.

According to this solid-state imaging element, the density difference of the accumulation charges can be increased at least while the charges are stored in the storage unit. Therefore, it is possible to strengthen the electric field to be generated, with respect to the direction parallel to the substrate surface.

Furthermore, as for the solid-state imaging element having the above characteristics, a separation unit having a higher impurity concentration than a surrounding area is preferably formed in a boundary between the pixel regions in the substrate.

According to this solid-state imaging element, it is possible to heighten the potential barrier in the boundary between the pixel regions in the substrate. Therefore, the charge generated by the photoelectric conversion in each pixel region can be efficiently moved to and stored in the storage unit in the pixel region. In addition, the pixel region can be defined as a region sandwiched between the separation units. In this case, when the density of the accumulation charges with respect to the direction parallel to the substrate surface varies based on an arrangement of the pixel regions, it can be said that the density varies based on an arrangement of the separation units.

Further, preferably, the solid-state imaging element having the above characteristics further includes:

a wiring layer provided on the substrate beside a first substrate surface, for controlling the charge having the first polarity and stored in the storage unit, wherein

light enters the substrate through a second substrate surface opposite to the first substrate surface, and the charge having the first polarity and generated by the photoelectric conversion of the light is stored in the storage unit, and

the fixed charge layer is provided above at least the second substrate surface.

In this case, as for the back side irradiation type solid-state imaging element, the dark current can be effectively reduced.

Further, in the solid-state imaging element having the above characteristics, the fixed charge layer preferably includes at least one of hafnium oxide, aluminum oxide, zirconium oxide, tantalum oxide, titanium oxide, tungsten oxide, zinc oxide, yttrium oxide, oxide of lanthanoid, silicon oxide, nickel oxide, cobalt oxide, and copper oxide.

Although depending on a film formation condition of the impurity or the like, “hafnium oxide, aluminum oxide, zirconium oxide, tantalum oxide, titanium oxide, tungsten oxide, zinc oxide, yttrium oxide, and oxide of lanthanoid, silicon oxide” in the above description each have the negative fixed charge, and “nickel oxide, cobalt oxide, and copper oxide” each have the positive fixed charge, in general.

Further, in the solid-state imaging element having the above characteristics, a film thickness in a center of a region immediately above the storage unit in the fixed charge layer is preferably,

0.75×{500/(4×N)+K×500/(2×N)} nm or more, and

1.25×{560/(4×N)+K×560/(2×N)} nm or less,

when N represents a refractive index of the fixed charge layer, and K represents an integer of 0 or more.

According to this solid-state imaging element, the light can be prevented from being reflected in the fixed charge layer. Therefore, sensitivity of the solid-state imaging element can be improved.

### Effects of the Invention

According to the solid-state imaging element having the above characteristics, it is possible to improve the probability that the charge making the dark current disappears due to the recombination before the charge reaches the storage unit, so that the dark current can be effectively reduced.

### BRIEF DESCRIPTION OF THE DRAWINGS

FIG. 1 is a cross-sectional view showing one example of an overall structure of a solid-state imaging element according to an embodiment of the present invention.

FIG. 2 is an essential part cross-sectional view showing a first specific example of a structure to reduce a dark current, in the solid-state imaging element according to the embodiment of the present invention.

FIG. 3 is an essential part cross-sectional view showing a second specific example of the structure to reduce the dark current, in the solid-state imaging element according to the embodiment of the present invention.

FIG. 4 is an essential part cross-sectional view showing a third specific example of the structure to reduce the dark current, in the solid-state imaging element according to the embodiment of the present invention.

FIG. 5 is an essential part cross-sectional view showing a fourth specific example of the structure to reduce the dark current, in the solid-state imaging element according to the embodiment of the present invention.

FIG. 6 is an essential part cross-sectional view showing a fifth specific example of the structure to reduce the dark current, in the solid-state imaging element according to the embodiment of the present invention.

FIG. 7 is an essential part cross-sectional view showing a sixth specific example of the structure to reduce the dark current, in the solid-state imaging element according to the embodiment of the present invention.

FIG. 8 is an essential part cross-sectional view showing a seventh specific example of the structure to reduce the dark current, in the solid-state imaging element according to the embodiment of the present invention.

FIG. 9A is a top view of a substrate to describe one example of a method of forming a barrier unit and an attraction unit.

FIG. 9B is a top view of a substrate to describe one example of a method of forming a barrier unit and an attraction unit.

FIG. 10 is an essential part cross-sectional view showing one example of a structure of a solid-state imaging element in a case where a pixel that is not irradiated with light is provided.

FIG. 11 is an essential part cross-sectional view showing another example of the structure to reduce the dark current, in the solid-state imaging element according to the embodiment of the present invention.

FIG. 12 is an essential part cross-sectional view showing another example of the structure to reduce the dark current, in the solid-state imaging element according to the embodiment of the present invention.

FIG. 13 is an essential part cross-sectional view showing another example of the structure to reduce the dark current, in the solid-state imaging element according to the embodiment of the present invention.

FIG. 14 is an essential part cross-sectional view showing another example of the structure to reduce the dark current, in the solid-state imaging element according to the embodiment of the present invention.

FIG. 15 is a top view of a substrate to describe one example of a structure of an electrode layer.

FIG. 16 is an essential part cross-sectional view showing another example of the structure to reduce the dark current, in the solid-state imaging element according to the embodiment of the present invention.

### MODE FOR CARRYING OUT THE INVENTION

Hereinafter, a description will be given to a case where the present invention is applied to a back side irradiation type solid-state imaging element serving as a solid-state imaging element according to an embodiment of the present invention, in order to specify the description. However, the solid-state imaging element to which the present invention can be applied is not limited to the back side irradiation type solid-state imaging element, and may be a front side irradiation type solid-state imaging element.

### <<Overall Structure Example of Solid-State Imaging Element>>

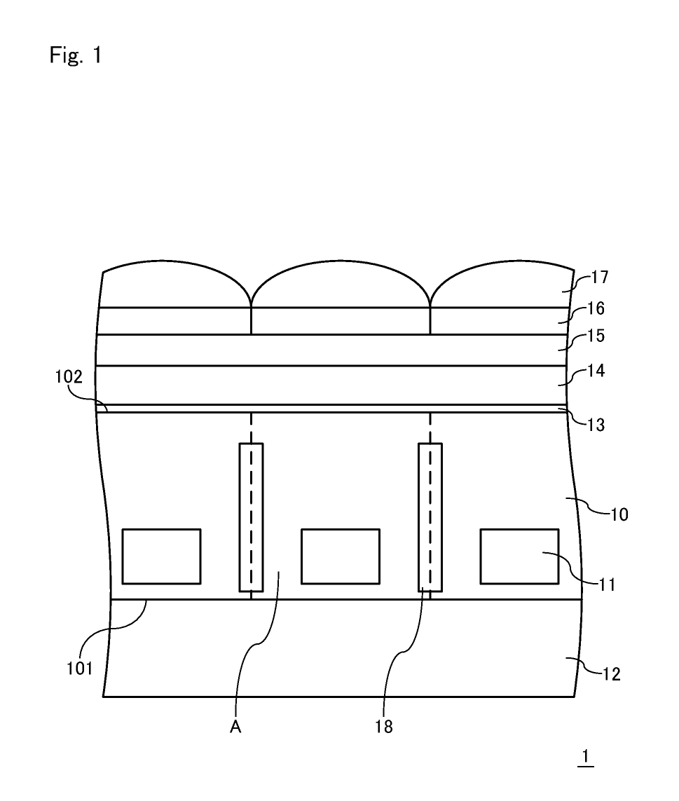

First, one example of an overall structure of the solid-state imaging element according to the embodiment of the present invention will be described with reference to the drawings. FIG. 1 is a cross-sectional view showing the one example of the overall structure of the solid-state imaging element according to the embodiment of the present invention. In addition, the drawing in this specification omits a hatching to show a cross-sectional surface, in order to clarify the drawing.

As shown in FIG. 1, a solid-state imaging element 1 includes a substrate 10, a storage unit 11 formed in the substrate 10 and storing electric charges generated by photoelectric conversion, a wiring layer 12 provided on one surface (hereinafter, it is referred to as a first substrate surface 101) of the substrate 10, a base layer 13 provided on the other surface (a surface opposite to the first substrate surface 101, and hereinafter, it is referred to as a second substrate surface 102) of the substrate 10, a fixed charge layer 14 provided on the base layer 13 and having positive or negative fixed charges, an insulating layer 15 provided on the fixed charge layer 14 and formed of insulator, a color filter 16 provided on the insulating layer 15 and selectively transmitting light having a predetermined color (wavelength), an on-chip lens 17 provided on the color filter 16 and collecting incident light and transferring it to the color filter 16, and a separation unit 18 formed in a boundary between pixel regions A in the substrate 10.

The substrate 10 is formed of p-type or n-type semiconductor. The storage unit 11 is formed of semiconductor having a conductivity type opposite to that of the substrate 10, and the substrate 10 and the storage unit 11 constitute a photodiode. In addition, the storage unit 11 is formed in a center region of the pixel region A (midway between the adjacent separation units 18) in the substrate 10, and the storage units 11 are arranged with respect to a direction parallel to the second substrate surface 102 (and the first substrate surface 101) with predetermined periodicity. More specifically, as shown in FIG. 1, the storage units 11 are arranged at predetermined intervals with respect to the direction parallel to the second substrate surface 102. In addition, FIG. 1 shows that the pixel regions A and the storage units 11 are arranged at predetermined intervals in a lateral direction in a sheet surface, but the pixel regions A and the storage units 11 are arranged at predetermined intervals also in a back-and-forth direction in the sheet surface.

Furthermore, the color filters 16 and the on-chip lenses 17 are arranged similarly to the pixel regions A and the storage units 11. More specifically, the pixel regions A and the storage units 11, and the color filters 16 and the on-chip lenses 17 are arranged in a form of a matrix, respectively (Bayer arrangement is provided with respect to the color filters 16).

The separation unit 18 is formed of semiconductor having the same conductivity type as that of the substrate 10, and the impurity concentration of the separation unit 18 is higher than the impurity concentration of the surrounding substrate 10 (a potential barrier is higher). Therefore, the charge generated by the photoelectric conversion in the pixel region A is efficiently moved to and stored in the storage unit 11 in the pixel region A. Furthermore, the pixel region A can be defined as a region sandwiched between the separation units 18.

The light to be inputted to the solid-state imaging element 1 is collected by the on-chip lens 17, and transferred to the color filter 16. The color filter 16 selectively transmits light having a predetermined color (wavelength). The light, has passed through the color filter 16, passes through the insulating layer 15, the fixed charge layer 14, and the base layer 13, and enters the substrate 10 through the second substrate surface 102. Then, electrons and holes are generated by the photoelectric conversion of the incident light in the substrate 10, and one of them is stored in the storage unit 11.

The wiring layer 12 includes an insulator, and a conductor such as a wiring or an electrode formed in the insulator based on a method of processing the charge, used in the solid-state imaging element 1. More specifically, the conductor in the wiring layer 12 includes a gate electrode to transfer the charges stored in the storage unit 11 to another region of the substrate 10, and an electrode and a wiring to read the charges stored in the storage unit 11 out of the substrate 10.

The base layer 13 is provided between the second substrate surface 102 and the fixed charge layer 14, and across the base layer 13, an accumulation charge having a (negative or positive) polarity opposite to that of the positive or negative fixed charges in the fixed charge layer 14 is accumulated in the second substrate surface 102. At this time, each unit in the solid-state imaging element 1 is configured such that a density of the accumulation charges in the second substrate surface 102 varies based on the periodicity of the arrangement of the storage units 11, with respect to the direction parallel to the second substrate surface 102 (its specific example will be described below).

As for the solid-state imaging element 1 according to the embodiment of the present invention, an electric field is generated based on a distribution of the density of the accumulation charges, with respect to the direction parallel to the second substrate surface 102. Therefore, charges making a dark current generated due to a defect of the second substrate surface 102 move not only toward the storage unit 11 but also move along the second substrate surface 102, so that the charge takes a longer route and a longer time to reach the storage unit 11, compared to a case where the density of the accumulation charges is uniform with respect to the direction parallel to the second substrate surface 102. Therefore, it is possible to improve the probability that the charge disappears due to the recombination before it reaches the storage unit 11, so that the dark current can be reduced.

### <<Specific Example of Structure to Reduce Dark Current>>

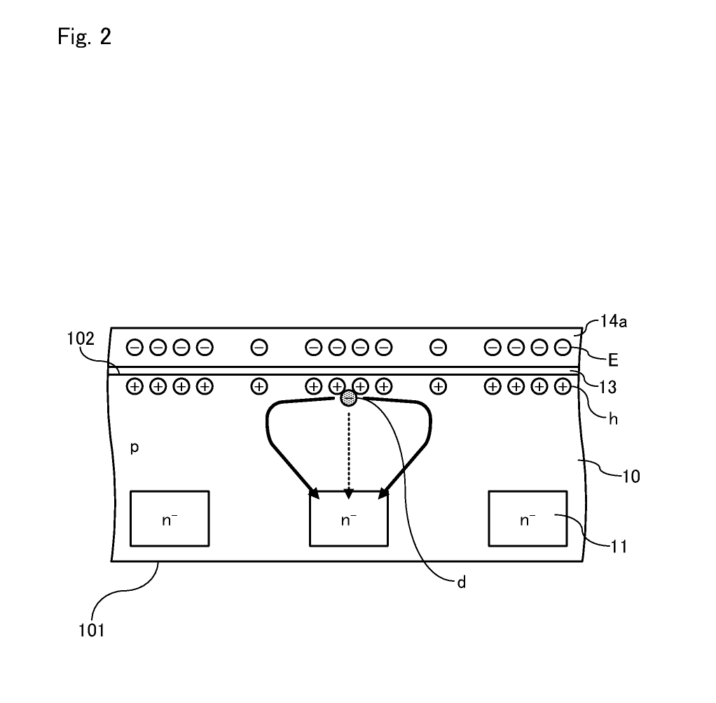

Hereinafter, a description will be given to a specific example of a structure to reduce the dark current with the electric field generated based on the distribution of the density of the accumulation charges as described above, in the solid-state imaging element 1 according to the embodiment of the present invention, with reference to the drawings. FIGS. 2 to 8 are essential part cross-sectional views which show first to seventh specific examples of the structures to reduce the dark current, in the solid-state imaging element according to the embodiment of the present invention. In addition, the pixel region A and the separation unit 18 are not shown in FIGS. 2 to 8 to simplify the description.

Here, it is to be noted that the description will be given to a case where the substrate 10 is formed of p-type (p) semiconductor, the storage unit 11 is formed of n-type (n⁻) semiconductor and stores the electrons generated by the photoelectric conversion, and the fixed charge layer 14 has negative fixed charges, in order to specify the description.

Furthermore, the description will be given to a case where the density of the accumulation charges in the second substrate surface 102 varies based on the arrangement of the pixel regions A and the arrangement of the storage units 11. More specifically, the description will be given to a case where the density of the accumulation charges in the second substrate surface 102 becomes high in a region getting close to the storage unit 11 (such as a region just above the storage unit 11, which is the same for a part described as “the region close to the storage unit 11” below, unless otherwise stated), while the density becomes low in a region getting away from the storage unit 11 (such as a region provided between the regions just above the storage units 11, that is, a boundary region of the pixel regions A (region just above the separation unit 18), which is the same for a part described as “the region away from the storage unit 11” below, unless otherwise stated), with respect to the direction parallel to the second substrate surface 102. In addition, a case other than this will be described in <<variation and the like>> below.

Furthermore, the term that the semiconductor composing the substrate 10 has the p type means that a conductivity type of a region having an element structure in the substrate 10 is the p type, which includes not only a case where the conductivity type of the substrate 10 is the p type as a whole, but also a case where a conductivity type of a well of the substrate 10 is the p type (a case where a p-type well is formed in an entirely n-type substrate, for example), as a matter of course.

The substrate 10 is composed of silicon, for example. In this case, as a p-type impurity, boron or boron fluoride may be used. In addition, in this case, as an n-type impurity, phosphor or arsenic may be used. Furthermore, each impurity is implanted into the substrate 10 by an ion implantation method, for example. The storage unit 11 is formed by implanting the n-type impurity from the first substrate surface 101 into the substrate 10, for example. In addition, the storage unit 11 may be provided in a position apart from the first substrate surface 101 by implanting the p-type impurity from the first substrate surface 101 into the substrate 10 when the storage unit 11 is formed (buried type photodiode may be provided).

The insulator in the insulating layer 15 and the wiring layer 12 is composed of silicon oxide, for example. Furthermore, the fixed charge layer 14 in the specific example which will be described below has negative fixed charges. In addition, although depending on a film forming condition of the impurity or the like, the negative fixed charge is provided in a hafnium oxide, aluminum oxide, zirconium oxide, tantalum oxide, titanium oxide, tungsten oxide, zinc oxide, yttrium oxide, oxide of lanthanoid, and silicon oxide, while the positive fixed charge is provided in a nickel oxide, cobalt oxide, and copper oxide, in general. The fixed charge layer 14 is to be composed of at least one material of those. Furthermore, an impurity such as silicon or nitrogen may be added to the fixed charge layer 14.

In addition, the base layer 13 is formed of insulator such as silicon oxide, silicon nitride, or silicon oxynitride. In this case, a defect density causing the dark current can be reduced in the second substrate surface 102 of the substrate 10 provided under the base layer 13, which is preferable.

Furthermore, as for the specific examples of the structures to reduce the dark current which will be described below, they may be partially or wholly combined as long as there is no contradiction, as a matter of course.

### First Specific Example

With reference to FIG. 2, a first specific example of the structure to reduce the dark current will be described. In addition, a thick solid-line arrow shown in FIG. 2 shows a route that a charge d making the dark current is likely to take without being recombined when the structure of the first specific example is used. Meanwhile, a broken-line arrow shown in FIG. 2 shows a route that the charge d making the dark current is likely to take without being recombined when the structure of the first specific example is not used.

As shown in FIG. 2, according to the structure of the first specific example, a density of negative fixed charges E is high in a region close to the storage unit 11, in a fixed charge layer 14a, while the density of the negative fixed charges E is low in a region away from the storage unit 11, in the fixed charge layer 14a, with respect to the direction parallel to the second substrate surface 102. Therefore, a density of the accumulation charges h in the second substrate surface 102 becomes high in a region getting close to the storage unit 11, and becomes low in a region getting away from the storage unit 11, with respect to the direction parallel to the second substrate surface 102, so that an electric field is generated with respect to that direction.

In this case, as shown by the thick solid line in FIG. 2, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, in a case where the structure of the first specific example is not used (the density of the accumulation charges h is uniform with respect to the direction parallel to the second substrate surface 102), as shown by the broken line in FIG. 2, after being generated in the second substrate surface 102, the charge d making the dark current is likely to directly move toward the storage unit 11.

As described above, when the structure of the first specific example is used, the charge d making the dark current takes a longer route and a longer time to reach the storage unit 11, so that it is possible to improve the probability that the charge d disappears due to the recombination before the charge d reaches the storage unit 11. Furthermore, since the charge d (electron) moves in the accumulation charges h (holes), the charge d can effectively disappear due to the recombination.

In addition, the above fixed charge layer 14a can be obtained by differentiating a heat treatment method applied to the region close to the storage unit 11, in the fixed charge layer 14a, from a heat treatment method applied to the region away from the storage unit 11, in the fixed charge layer 14a, with respect to the direction parallel to the second substrate surface 102. For example, in a case where the fixed charge layer 14a is composed of material which can increase the negative fixed charges E (such as hafnium oxide) when it is crystallized by the heat treatment after being formed, the above fixed charge layer 14a can be obtained by varying a heat treatment temperature based on the above region (the region to have the high density of the negative fixed charges E is subjected to the heat treatment at high temperature, while the region to have the low density of the negative fixed charges E is subjected to the heat treatment at low temperature).

Furthermore, the above fixed charge layer 14a can be obtained by differentiating an additive condition of an impurity in the region close to the storage unit 11, in the fixed charge layer 14a, from an additive condition of the impurity in the region away from the storage unit 11, in the fixed charge layer 14a, with respect to the direction parallel to the second substrate surface 102. For example, the above fixed charge layer 14a can be obtained by selectively adding an impurity that can decrease the density of the negative fixed charges E by its addition (or can increase the density of the negative fixed charges E, or both of them), based on the above region, or differentiating its additive amount based on the respective regions.

### Second Specific Example

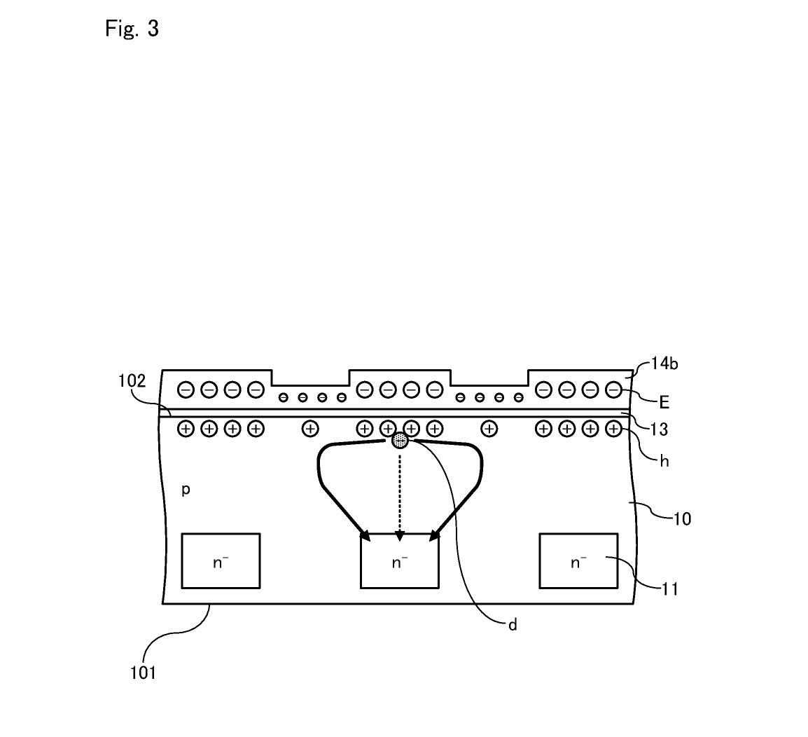

With reference to FIG. 3, a second specific example of the structure to reduce the dark current will be described. In addition, a thick solid-line arrow shown in FIG. 3 shows a route that the charge d making the dark current is likely to take without being recombined when the structure of the second specific example is used. Meanwhile, a broken-line arrow shown in FIG. 3 shows a route that the charge d making the dark current is likely to take without being recombined when the structure of the second specific example is not used.

As shown in FIG. 3, according to the structure of the second specific example, a film thickness of a fixed charge layer 14b in a region close to the storage unit 11 is large, while a film thickness of the fixed charge layer 14b in a region away from the storage unit 11 is small, with respect to the direction parallel to the second substrate surface 102. Therefore, the density of the accumulation charges h in the second substrate surface 102 becomes high in the region getting close to the storage unit 11, while it becomes low in the region getting away from the storage unit 11, with respect to the direction parallel to the second substrate surface 102, so that the electric field is generated with respect to that direction.

In this case, as shown by the thick solid line in FIG. 3, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, when the structure of the second specific example is not used (the density of the accumulation charges h is uniform with respect to the direction parallel to the second substrate surface 102), as shown by the broken line in FIG. 3, after being generated in the second substrate surface 102, the charge d making the dark current is likely to directly move toward the storage unit 11.

As described above, when the structure of the second specific example is used, the charge d making the dark current takes the longer route and the longer time to reach the storage unit 11, so that it is possible to improve the probability that the charge d disappears due to the recombination before it reaches the storage unit 11. Furthermore, since the charge d (electron) moves in the accumulation charges h (holes), the charge d can effectively disappear due to the recombination.

In addition, the above fixed charge layer 14b can be formed by etching the region whose film thickness is to be small, or can be formed by selectively forming a film in the region whose film thickness is to be large after the film having the uniform film thickness is formed.

### Third Specific Example

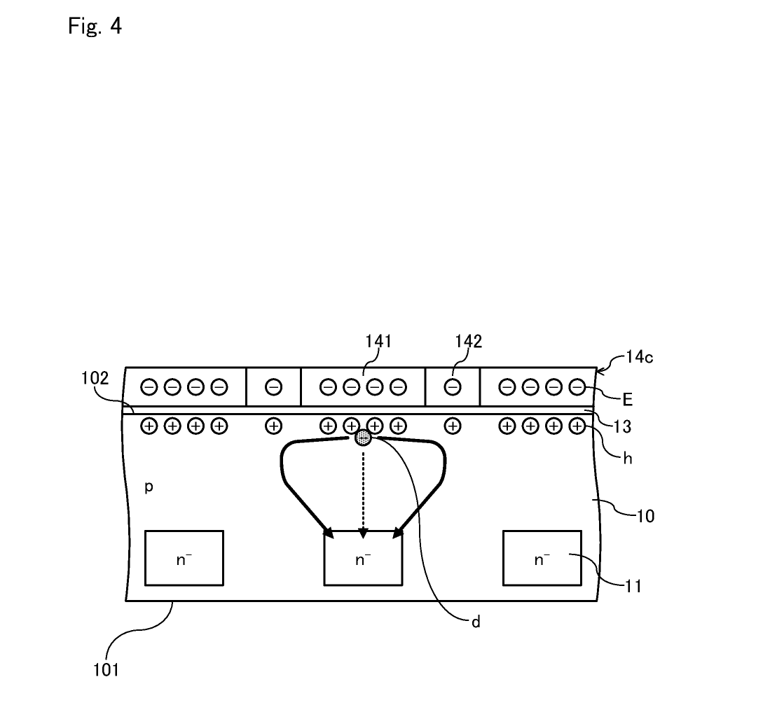

With reference to FIG. 4, a third specific example of the structure to reduce the dark current will be described. In addition, a thick solid-line arrow shown in FIG. 4 shows a route that the charge d making the dark current is likely to take without being recombined when the structure of the third specific example is used. Meanwhile, a broken-line arrow shown in FIG. 4 shows a route that the charge d making the dark current is likely to take without being recombined when the structure of the third specific example is not used.

As shown in FIG. 4, according to the structure of the third specific example, at least one part of a region 141 close to the storage unit 11, in a fixed charge layer 14c is composed of material having a high density of the negative fixed charges E, while at least one part of a region 142 away from the storage unit 11, in the fixed charge layer 14c is composed of material having a low density of the negative fixed charges E, with respect to the direction parallel to the second substrate surface 102. Therefore, the density of the accumulation charges h in the second substrate surface 102 becomes high in the region getting close to the storage unit 11, while it becomes low in the region getting away from the storage unit 11, with respect to the direction parallel to the second substrate surface 102, so that the electric field is generated with respect to that direction.

In this case, as shown by the thick solid line in FIG. 4, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, when the structure of the third specific example is not used (the density of the accumulation charges h is uniform with respect to the direction parallel to the second substrate surface 102), as shown by the broken line in FIG. 4, after being generated in the second substrate surface 102, the charge d making the dark current is likely to directly move toward the storage unit 11.

As described above, when the structure of the third specific example is used, the charge d making the dark current takes the longer route and the longer time to reach the storage unit 11, so that it is possible to improve the probability that the charge d disappears due to the recombination before it reaches the storage unit 11. Furthermore, since the charge d (electron) moves in the accumulation charges h (holes), the charge d can effectively disappear due to the recombination.

In addition, the above fixed charge layer 14c can be formed by separately forming the regions 141 and 142, for example. Furthermore, other than the case where at least one part of the regions 141 and one part of the region 142 are composed of materials having different densities of the negative fixed charges E, even when they are composed of materials having different work functions, the same effect can be obtained. In this case, at least one part of the region 141 is to be composed of material having a large work function difference, while at least one part of the region 142 is to be composed of material having a small work function difference (close to a work function of silicon).

### Fourth Specific Example

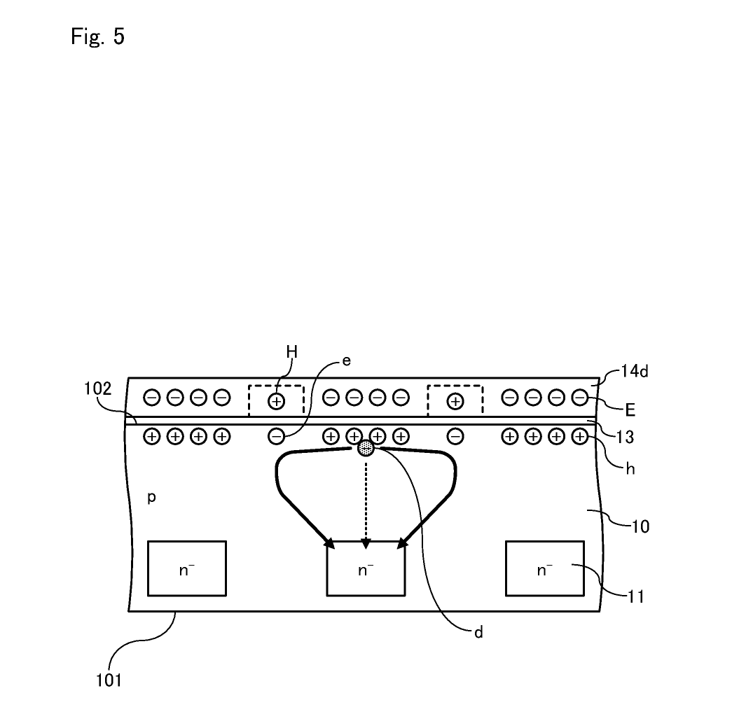

With reference to FIG. 5, a fourth specific example of the structure to reduce the dark current will be described. In addition, a thick solid-line arrow shown in FIG. 5 shows a route that the charge d making the dark current is likely to take without being recombined when the structure of the fourth specific example is used. Meanwhile, a broken-line arrow shown in FIG. 5 shows a route that the charge d making the dark current is likely to take without being recombined when the structure of the fourth specific example is not used.

As shown in FIG. 5, according to the structure of the fourth specific example, a region close to the storage unit 11, in a fixed charge layer 14d has the negative fixed charge E, while a region away from the storage unit 11, in the fixed charge layer 14d has a positive fixed charge H, with respect to the direction parallel to the second substrate surface 102. Therefore, the density of the accumulation charges h (holes) in the second substrate surface 102 becomes high in the region getting close to the storage unit 11, and becomes low in the region getting away from the storage unit 11 (an accumulation charge e (electron) exists), with respect to the direction parallel to the second substrate surface 102, so that the electric field is generated in that direction. Especially, the electric field is stronger than the electric field generated only due to the density difference of the accumulation charges h.

In this case, as shown by the thick solid line in FIG. 5, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, when the structure of the fourth specific example is not used (the density of the accumulation charges h is uniform with respect to the direction parallel to the second substrate surface 102), as shown by the broken line in FIG. 5, after being generated in the second substrate surface 102, the charge d making the dark current is likely to directly move toward the storage unit 11.

As described above, when the structure of the fourth specific example is used, the charge d making the dark current takes the longer route and the longer time to reach the storage unit 11, so that it is possible to improve the probability that the charge d disappears due to the recombination before the charge d reaches the storage unit 11. Especially, according to the structure in the fourth specific example, since the stronger electric field can be generated with respect to the direction parallel to the second substrate surface 102, it is possible to further improve the probability that the charge d disappears due to the recombination before the charge d reaches the storage unit 11. Furthermore, since the charge d (electron) moves in the accumulation charges h (holes), the charge d can effectively disappear due to the recombination.

In addition, similar to the third specific example, the above fixed charge layer 14d can be obtained by differentiating a material of at least one part in the region close to the storage unit 11, in the fixed charge layer 14d, from a material of at least one part in the region away from the storage unit 11, in the fixed charge layer 14d, with respect to the direction parallel to the second substrate surface 102. In this case, as the material having the positive fixed charge, silicon nitride or silicon oxynitride can be used. Alternatively, similar to the first specific example, the fixed charge layer 14d can be obtained by differentiating an additive condition of an impurity in the region close to the storage unit 11, in the fixed charge layer 14d, from an additive condition of the impurity in the region away from the storage unit 11, in the fixed charge layer 14d, with respect to the direction parallel to the second substrate surface 102.

### Fifth Specific Example

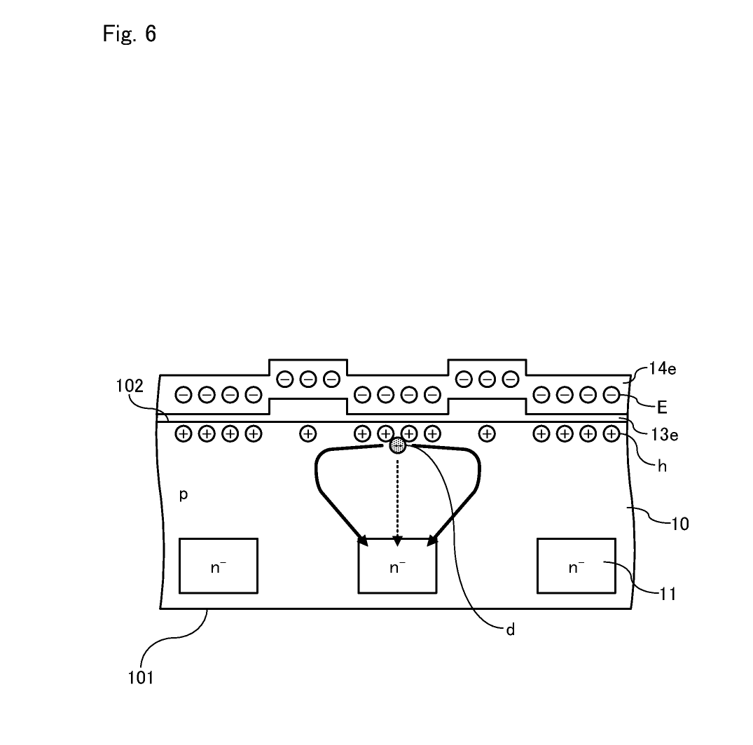

With reference to FIG. 6, a fifth specific example of the structure to reduce the dark current will be described. In addition, a thick solid-line arrow shown in FIG. 6 shows a route that the charge d making the dark current is likely to take without being recombined when the structure of the fifth specific example is used. Meanwhile, a broken-line arrow shown in FIG. 6 shows a route that the charge d making the dark current is likely to take without being recombined when the structure of the fifth specific example is not used.

As shown in FIG. 6, according to the structure of the fifth specific example, a film thickness of a region close to the storage unit 11 is small in a base layer 13e, while a film thickness of a region away from the storage unit 11 is large in the base layer 13e, with respect to the direction parallel to the second substrate surface 102. Thus, a distance between a region close to the storage unit 11, in a fixed charge layer 14e and the second substrate surface 102 is small, while a distance between a region away from the storage unit 11, in the fixed charge layer 14e and the second substrate surface 102 is large, with respect to the direction parallel to the second substrate surface 102. Therefore, the density of the accumulation charges h in the second substrate surface 102 becomes higher in the region getting close to the storage unit 11 and becomes low in the region getting away from the storage unit 11, with respect to the direction parallel to the second substrate surface 102, so that the electric field is generated with respect to that direction.

In this case, as shown by the thick solid line in FIG. 6, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, when the structure of the fifth specific example is not used (the density of the accumulation charges h is uniform with respect to the direction parallel to the second substrate surface 102), as shown by the broken line in FIG. 6, after being generated in the second substrate surface 102, the charge d making the dark current is likely to directly move toward the storage unit 11.

As described above, when the structure of the fifth specific example is used, the charge d making the dark current takes the longer route and the longer time to reach the storage unit 11, so that it is possible to improve the probability that the charge d disappears due to the recombination before the charge d reaches the storage unit 11. Furthermore, since the charge d (electron) moves in the accumulation charges h (holes), the charge d can effectively disappear due to the recombination.

In addition, the above base layer 13e can be formed by etching the region whose film thickness is to be reduced or can be formed by selectively forming a film in the region whose film thickness is to be increased after a film having a uniform film thickness is formed. Furthermore, the above fixed charge layer 14e can be obtained by forming a uniform film on the base layer 13e having uneven film thicknesses.

### Sixth Specific Example

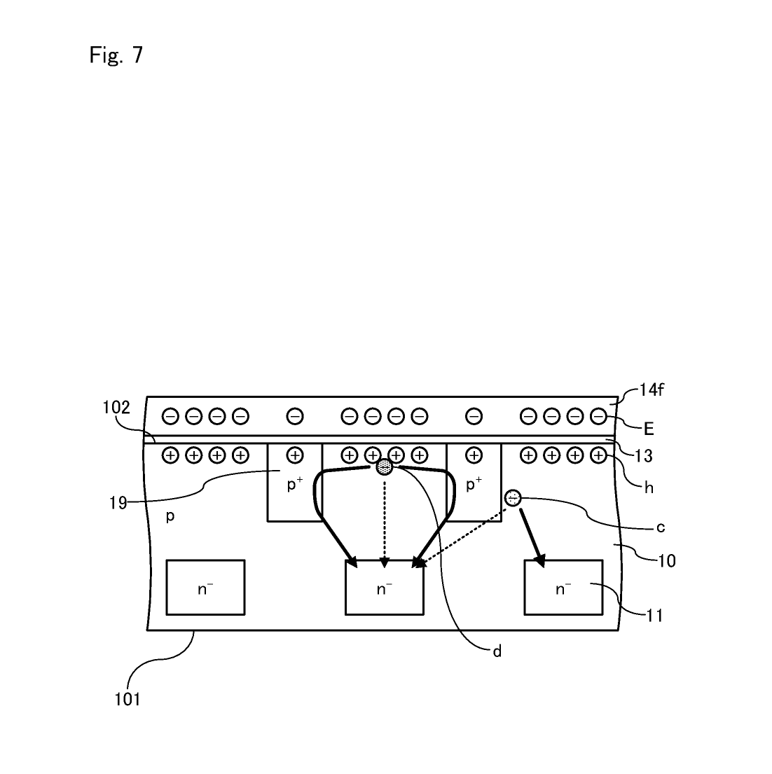

With reference to FIG. 7, a sixth specific example of the structure to reduce the dark current will be described. In addition, thick solid-line arrows shown in FIG. 7 show routes that the charge d making the dark current and a charge c generated by photoelectric conversion are likely to take without being recombined when the structure of the sixth specific example is used. Meanwhile, broken-line arrows shown in FIG. 7 show routes that the charge d making the dark current and the charge c generated by the photoelectric conversion are likely to take without being recombined when the structure of the sixth specific example is not used.

As shown in FIG. 7, according to the structure of the sixth specific example, a fixed charge layer 14f is provided similarly to the fixed charge layer 14a (refer to FIG. 2) shown in the first specific example, and the electric field is generated with respect to the direction parallel to the second substrate surface 102. Furthermore, according to the structure of the sixth specific example, a p-type (p⁺) barrier unit 19 having a higher impurity concentration than a surrounding part is formed in a region away from the storage unit 11, in the substrate 10, with respect to the direction parallel to the second substrate surface 102.

In this case, as shown by the thick solid line in FIG. 7, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, when the structure of the sixth specific example is not used (the density of the accumulation charges h is uniform with respect to the direction parallel to the second substrate surface 102), as shown by the broken line in FIG. 7, after being generated in the second substrate surface 102, the charge d making the dark current is likely to directly move toward the storage unit 11.

Furthermore, in this case, as shown by the thick solid line in FIG. 7, after being generated in the substrate 10 by the photoelectric conversion, the charge c tries to move so as to get away from the storage unit 11 due to the electric field generated with respect to the direction parallel to the second substrate surface 102, but the movement of the charge c is hindered by the barrier unit 19, and the charge c is likely to move toward the lower storage unit 11. Meanwhile, when the structure of the sixth specific example is not used (the barrier unit 19 is not formed), as shown by the broken line in FIG. 7, the charge c is likely to move so as to get away from the storage unit 11 due to the electric field generated with respect to the direction parallel to the second substrate surface 102, and move not toward the storage unit 11 in which the charge c is originally to be stored, but toward an adjacent storage unit 11.

As described above, when the structure of the sixth specific example is used, the charge d making the dark current takes the longer route and the longer time to reach the storage unit 11, so that it is possible to improve the probability that the charge d disappears due to the recombination before the charge d reaches the storage unit 11. Furthermore, since the charge d (electron) moves in the accumulation charges h (holes), the charge d can effectively disappear due to the recombination.

Furthermore, when the structure of the sixth specific example is used, a potential barrier can be clearly provided between the adjacent storage units 11, so that it is possible to improve the probability that the charge c generated by the photoelectric conversion moves to the storage unit 11 in which the charge c is originally to be stored. Therefore, colors can be prevented from being mixed.

In addition, the above barrier unit 19 can be formed by implanting a p-type impurity into the substrate 10, for example. At this time, the p-type impurity may be implanted from the second substrate surface 102 into the substrate 10, may be implanted from the first substrate surface 101 into the substrate 10, or may be implanted from both surfaces. Furthermore, in the case where the p-type impurity is implanted from the first substrate surface 101 to the substrate 10, the wiring layer 12 and the like are not formed yet when the p-type impurity is implanted into the substrate 10, so that the heat treatment can be sufficiently performed.

Furthermore, the fixed charge layer 14f in the sixth specific example is similar to the fixed charge layer 14a (refer to FIG. 2) in the first specific example in order to specify the description, but the fixed charge layer 14f may be similar to the fixed charge layer in the other specific example, or may be the one other than the above.

### Seventh Specific Example

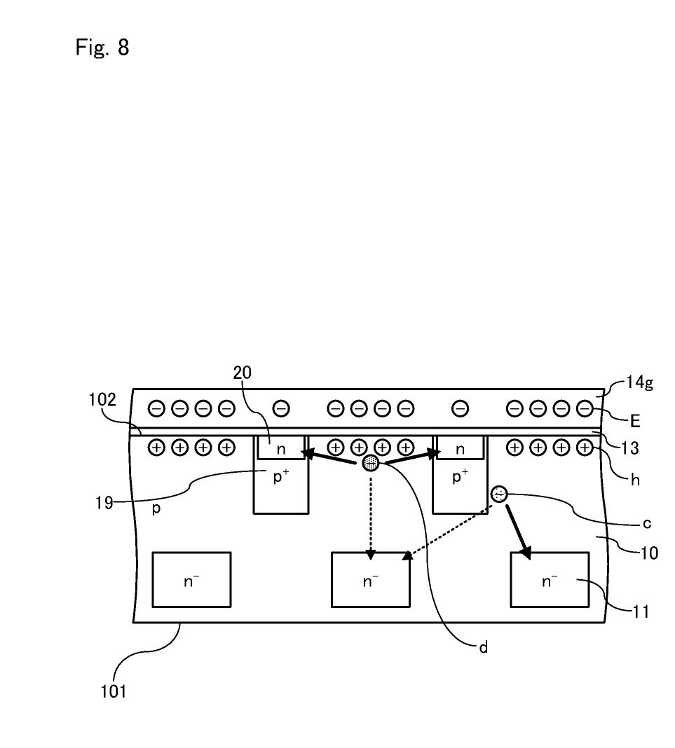

With reference to FIG. 8, a seventh specific example of the structure to reduce the dark current will be described. In addition, thick solid-line arrows shown in FIG. 8 show routes that the charge d making the dark current and the charge c generated by the photoelectric conversion are likely to take without being recombined when the structure of the seventh specific example is used. Meanwhile, broken-line arrows shown in FIG. 8 show routes that the charge d making the dark current and the charge c generated by the photoelectric conversion are likely to take without being recombined when the structure of the seventh specific example is not used.

As shown in FIG. 8, according to the structure of the seventh specific example, a fixed charge layer 14g similar to the fixed charge layer 14a (refer to FIG. 2) shown in the first specific example is provided, and the electric field is generated with respect to the direction parallel to the second substrate surface 102. Furthermore, according to the structure of the seventh specific example, the same barrier unit 19 as the barrier unit (refer to FIG. 7) shown in the sixth specific example is formed, and an n-type (n) attraction unit 20 is formed in the barrier unit 19 so as to be set beside the second substrate surface 102.

In this case, as shown by the thick solid line in FIG. 8, after being generated in the second substrate surface 102, the charge d making the dark current is likely to move so as to get away from the storage unit 11 due to the electric field generated with respect to the direction parallel to the second substrate surface 102, and then move toward the attraction unit 20. Meanwhile, when the structure of the seventh specific example is not used (the density of the accumulation charges h is uniform with respect to the direction parallel to the second substrate surface 102), as shown by the broken line in FIG. 8, after being generated in the second substrate surface 102, the charge d making the dark current is likely to directly move toward the storage unit 11.

Furthermore, in this case, as shown by the thick solid line in FIG. 8, after being generated in the substrate 10 by the photoelectric conversion, the charge c tries to move so as to get away from the storage unit 11 due to the electric field generated with respect to the direction parallel to the second substrate surface 102, but the movement of the charge c is hindered by the barrier unit 19, and the charge c is likely to move toward the lower storage unit 11. Meanwhile, when the structure of the seventh specific example is not used (the barrier unit 19 and the attraction unit 20 are not formed), as shown by the broken line in FIG. 8, the charge c is likely to move so as to get away from the storage unit 11 due to the electric field generated with respect to the direction parallel to the second substrate surface 102, and move not toward the storage unit 11 in which the charge c is originally to be stored, but toward an adjacent storage unit 11.

As described above, when the structure of the seventh specific example is used, the charge d making the dark current can be confined in the second substrate surface 102, and the charge d making the dark current takes the longer route and the longer time to reach the storage unit 11, so that it is possible to improve the probability that the charge d disappears due to the recombination before the charge d reaches the storage unit 11. Furthermore, since the charge d (electron) moves in the accumulation charges h (holes), the charge d can effectively disappear due to the recombination.

Furthermore, when the structure of the seventh specific example is used, a potential barrier can be clearly provided between the adjacent storage units 11, so that it is possible to improve the probability that the charge c generated by the photoelectric conversion moves to the storage unit 11 in which the charge c is originally to be stored. Therefore, colors can be prevented from being mixed.

In addition, the above attraction unit 20 can be formed by implanting an n-type impurity from the second substrate surface 102 into the barrier unit 19 formed in the substrate 10. In addition, the fixed charge layer 14g in the seventh specific example is similar to the fixed charge layer 14a (refer to FIG. 2) in the first specific example in order to specify the description, but it may be similar to any of the fixed charge layers in the other specific examples, or may be the one other than those.

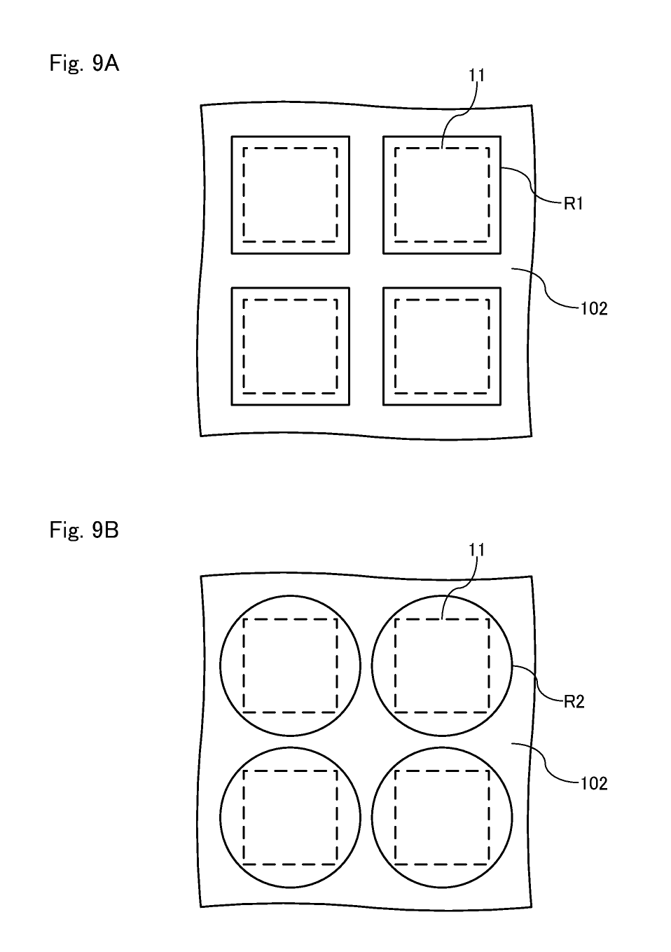

### <<Variation and the Like>>

[1] One example of a method of forming the barrier unit 19 and the attraction unit 20 described in the sixth and seventh specific examples will be described with reference to the drawings. Each of FIGS. 9A and 9B is a top view of the substrate to describe the one example of the method of forming the barrier unit and the attraction unit. In addition, each of FIGS. 9A and 9B is the top view taken from the second substrate surface 102 to the substrate 10.

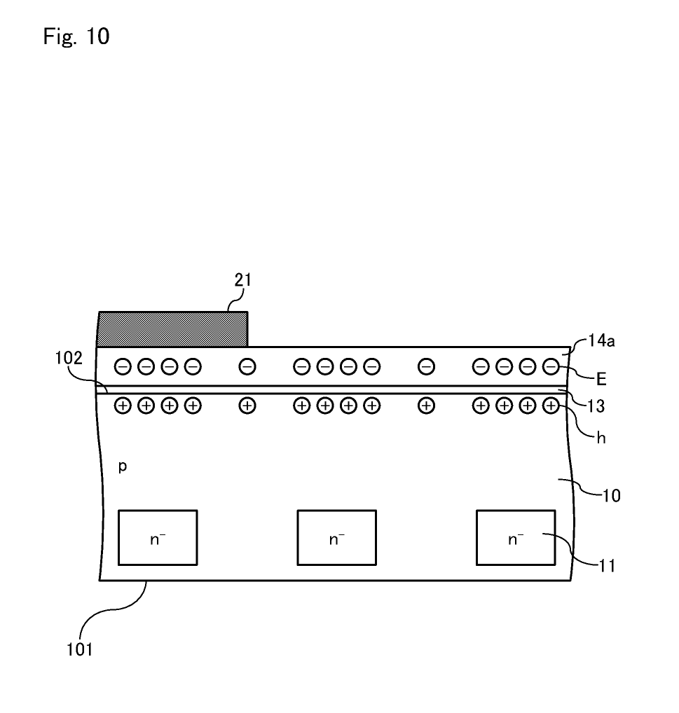

As shown in FIGS. 9A and 9B, according to the method of forming the barrier unit 19 and the attraction unit 20 in this example, a resist R1 or R2 is arranged at least just above the storage unit 11, and then impurities are implanted. Here, the resist R1 shown in FIG. 9A is rectangular, and the resist R2 shown in FIG. 9B is circular. With a view of improvement of shading characteristics of the solid-state imaging element 1 (reduce of luminance unevenness), each of the resists R1 and R2 is preferably in polygon with four sides or more, and more preferably in circle as shown in FIG. 9B.

[2] As for the solid-state imaging element 1 according to the embodiment of the present invention, a pixel (optical black) which is not irradiated with light may be provided at an end of the solid-state imaging element 1, in order to detect a noise content of the dark current or the like. One example of a structure of the solid-state imaging element 1 in this case will be described with reference to FIG. 10. FIG. 10 is an essential part cross-sectional view showing the one example of the structure of the solid-state imaging element having the pixel which is not irradiated with light. In addition, a description will be given to the case where the pixel which is not irradiated with light is provided in the solid-state imaging element in the above first specific example, in order to specify the description.

As shown in FIG. 10, in the case where the pixel which is not irradiated with light is provided, a light-blocking layer 21 is provided just above the storage unit 11 (left end in the drawing) in that pixel to block the light from entering the substrate 10. At this time, when the light-blocking layer 21 is provided on the fixed charge layer 14a, the charges making the dark current can be uniform in behavior in that pixel and the other ordinal pixel, so that it is possible to reduce a difference in dark current generated in the storage units 11 of each pixel, which is preferable.

[3] As described above, the description has been given to the structure in which the density of the accumulation charges h in the second substrate surface 102 becomes high in the region getting close to the storage unit 11 and becomes low in the region getting away from the storage unit 11 (refer to FIGS. 2 to 8, and 10), with respect to the direction parallel to the second substrate surface 102, but the distribution of the density of the accumulation charges h may be opposite to that in the structure in each of the above specific examples. That is, the density of the accumulation charges h in the second substrate surface 102 may become low in the region getting close to the storage unit 11 and become high in the region getting away from the storage unit 11, with respect to the direction parallel to the second substrate surface 102.

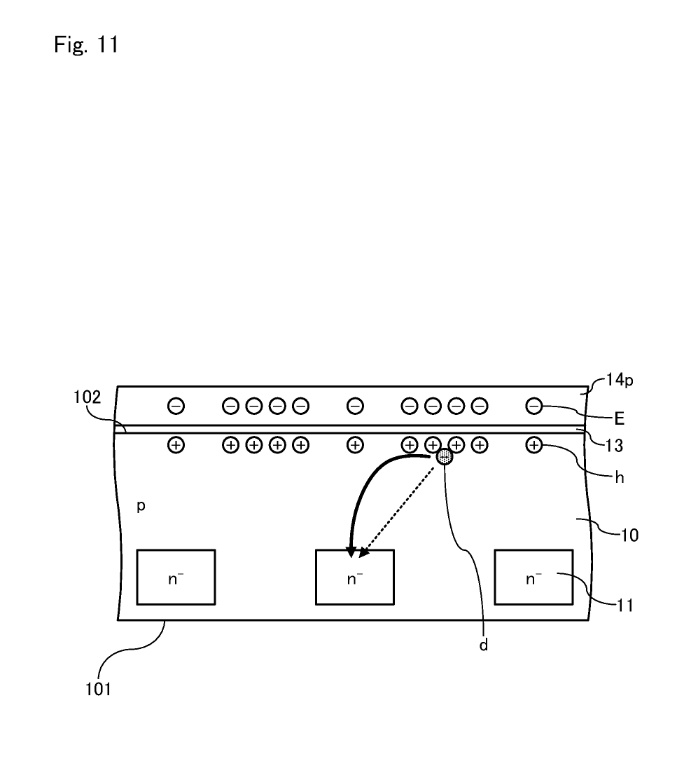

One example of a structure of the solid-state imaging element 1 in this case will be described with reference to FIG. 11. FIG. 11 is an essential part cross-sectional view showing another example of the structure to reduce the dark current in the solid-state imaging element according to this embodiment of the present invention. In addition, a thick solid-line arrow shown in FIG. 11 shows a route that the charge d making the dark current is likely to take without being recombined when the structure of this example is used. Meanwhile, a broken-line arrow shown in FIG. 11 shows a route that the charge d making the dark current is likely to take without being recombined when the structure of this example is not used. In addition, in order to specify the description, the description will be given to the structure of another example corresponding to the structure of the above first specific example (refer to FIG. 2).

As shown in FIG. 11, according to the structure of this example, a density of the negative fixed charges E is low in a region close to the storage unit 11, in a fixed charge layer 14p, while a density of the negative fixed charges E is high in a region away from the storage unit 11, in the fixed charge layer 14p, with respect to the direction parallel to the second substrate surface 102. Therefore, the density of the accumulation charges h in the second substrate surface 102 becomes low in the region getting close to the storage unit 11, and becomes high in the region getting away from the storage unit 11, with respect to the direction parallel to the second substrate surface 102, so that the electric field is generated with respect to that direction.

In this case, as shown by the thick solid line in FIG. 11, after being generated in the second substrate surface 102, the charge d making the dark current is likely to move so as to get close to the storage unit 11 due to the electric field generated with respect to the direction parallel to the second substrate surface 102, and then move toward the storage unit 11. Meanwhile, when the structure of this example is not used (the density of the accumulation charges h is uniform with respect to the direction parallel to the second substrate surface 102), as shown by the broken line in FIG. 11, after being generated in the second substrate surface 102, the charge d making the dark current is likely to directly move toward the storage unit 11.

As described above, when the structure of this example is used, the charge d making the dark current takes the longer route and the longer time to reach the storage unit 11, so that it is possible to improve the probability that the charge d disappears due to the recombination before the charge d reaches the storage unit 11. Furthermore, since the charge d (electron) moves in the accumulation charges h (holes), the charge d can effectively disappear due to the recombination.

Furthermore, according to the structure in this example, the charge (electron) generated by the photoelectric conversion moves so as not to get away from the storage unit 11 but to get close to it, with respect to the direction parallel to the second substrate surface 102. Therefore, it is possible to improve the probability that the charge generated by the photoelectric conversion moves to the storage unit 11 in which the charge is originally to be stored. As a result, colors can be prevented from being mixed.

In addition, as described in the above structures of the sixth and seventh specific examples, when the barrier unit 19 is provided, the colors can be also prevented from being mixed. However, it is necessary to implant the impurity into the substrate 10 and perform the heat treatment in order to form the barrier unit 19, which could destroy the structure which has been formed, and deteriorate the characteristics, depending on the timing and temperature of the heat treatment. On the other hand, according to the structure in this example, only by forming the fixed charge layer 14p above the second substrate surface 102, it is not necessary to implant the p-type impurity having the conductivity type opposite to that of the storage unit 11, so that it is not necessary to perform the heat treatment associated with the implantation of because the p-type impurity. Therefore, it is possible to prevent the destruction of the structure and the deterioration of the characteristics due to the heat treatment.

[4] In the above, the description has been given to the structure in which the fixed charge layer has the negative fixed charge, and the positive accumulation charge is accumulated in the second substrate surface 102 (refer to FIGS. 2 to 8, and FIGS. 10 and 11), but the polarities of the fixed charge and the accumulation charge may be opposite to those in the structure in each of the above specific examples. That is, the fixed charge layer may have the positive fixed charge, and the negative accumulation charge may be accumulated in the second substrate surface 102.

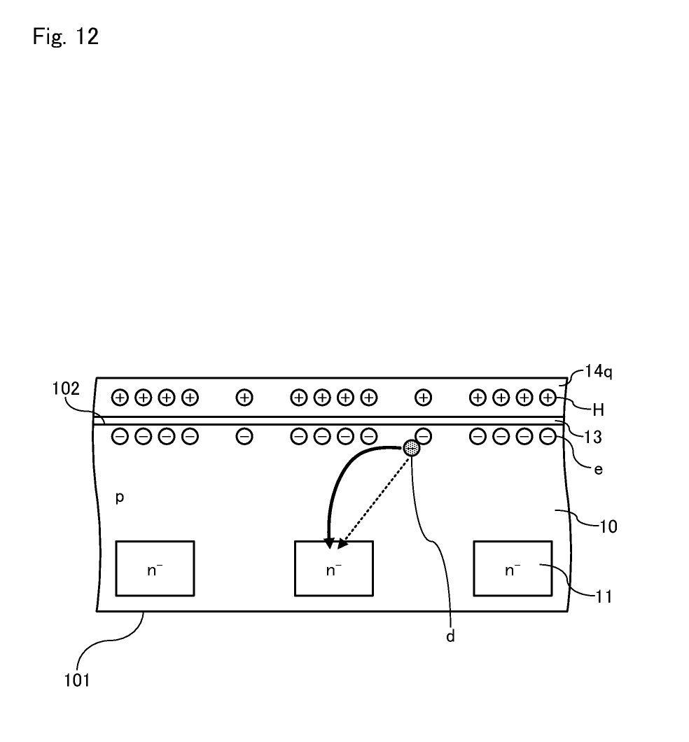

One example of a structure of the solid-state imaging element 1 in this case will be described with reference to FIG. 12. FIG. 12 is an essential part cross-sectional view showing another example of the structure to reduce the dark current in the solid-state imaging element according to the embodiment of the present invention. In addition, a thick solid-line arrow shown in FIG. 12 shows a route that the charge d making the dark current is likely to take without being recombined when the structure of this example is used. Meanwhile, a broken-line arrow shown in FIG. 12 shows a route that the charge d making the dark current is likely to take without being recombined when the structure of this example is not used. In addition, in order to specify the description, the description will be given to the structure of another example corresponding to the structure of the above first specific example (refer to FIG. 2).

As shown in FIG. 12, according to the structure of this example, a density of the positive fixed charges H is high in a region close to the storage unit 11, in a fixed charge layer 14q, while a density of the positive fixed charges H is low in a region away from the storage unit 11, in the fixed charge layer 14q, with respect to the direction parallel to the second substrate surface 102. Therefore, a density of accumulation charges e in the second substrate surface 102 becomes high in the region getting close to the storage unit 11, and becomes low in the region getting away from the storage unit 11, with respect to the direction parallel to the second substrate surface 102, so that the electric field is generated in that direction.

In this case, as shown by the thick solid line in FIG. 12, after being generated in the second substrate surface 102, the charge d making the dark current is likely to move so as to get close to the storage unit 11 due to the electric field generated with respect to the direction parallel to the second substrate surface 102, and then move toward the storage unit 11. Meanwhile, when the structure of this example is not used (the density of the accumulation charges e is uniform with respect to the direction parallel to the second substrate surface 102), as shown by the broken line in FIG. 12, after being generated in the second substrate surface 102, the charge d making the dark current is likely to directly move toward the storage unit 11.

As described above, when the structure of this example is used, the charge d making the dark current takes the longer route and the longer time to reach the storage unit 11, so that it is possible to improve the probability that the charge d disappears due to the recombination before the charge d reaches the storage unit 11. Furthermore, according to the structure in this example, the charge d generated by the photoelectric conversion moves so as not to get away from the storage unit 11 but to get close to the storage unit, with respect to the direction parallel to the second substrate surface 102. Therefore, it is possible to improve the probability that the charge generated by the photoelectric conversion moves to the storage unit 11 in which it is originally to be stored. As a result, colors can be prevented from being mixed. In addition, according to the structure of this example, only by forming the fixed charge layer 14q above the second substrate surface 102, the colors can be prevented from being mixed.

Furthermore, according to the structure of this example, the charge d (electron) moves among the accumulation charges e (electron). Therefore, according to the structure in this example, the charge d could be hard to disappear due to the recombination, compared to the structure in each of the above specific examples. However, even in the structure of this example, the charge d can preferably disappear by increasing a concentration of the p-type impurity in the substrate 10.

[5] In the above [4], the description has been given to the case where the density of the accumulation charges e in the second substrate surface 102 becomes high in the region getting close to the storage unit 11 and becomes low in the region getting away from the storage unit 11, with respect to the direction parallel to the second substrate surface 102 (refer to FIG. 12), but the distribution of the density of the accumulation charges e may be opposite to that in the above [4]. That is, the density of the accumulation charges e in the second substrate surface 102 may become low in the region getting close to the storage unit 11 and become high in the region getting away from the storage unit 11, with respect to the direction parallel to the second substrate surface 102.

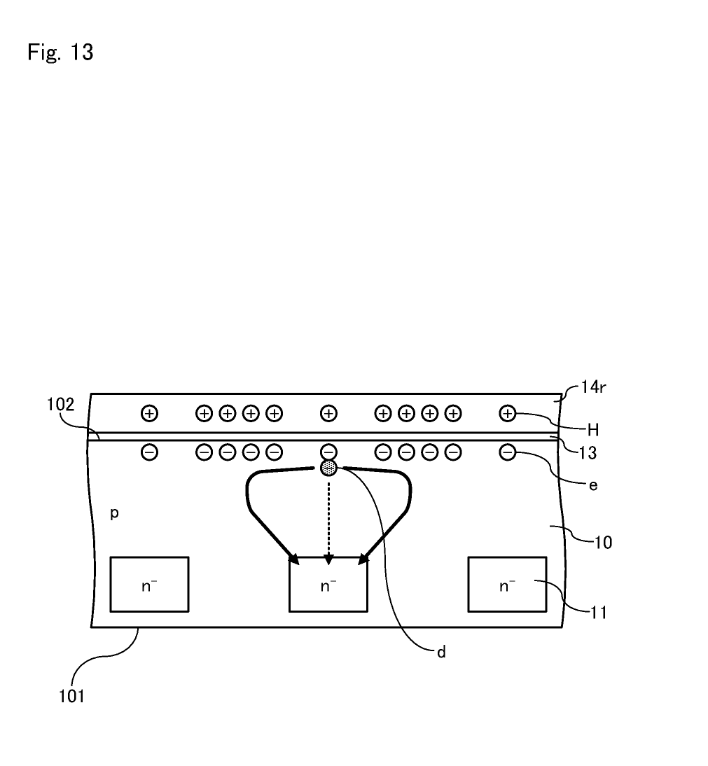

One example of a structure of the solid-state imaging element 1 in this case will be described with reference to FIG. 13. FIG. 13 is an essential part cross-sectional view showing another example of the structure to reduce the dark current in the solid-state imaging element according to the embodiment of the present invention. In addition, a thick solid-line arrow shown in FIG. 13 shows a route that the charge d making the dark current is likely to take without being recombined when the structure of this example is used. Meanwhile, a broken-line arrow shown in FIG. 13 shows a route that the charge d making the dark current is likely to take without being recombined when the structure of this example is not used. In addition, in order to specify the description, the description will be given to the structure of another example corresponding to the structure of the above first specific example (refer to FIG. 2).

As shown in FIG. 13, according to the structure of this example, a density of the positive fixed charges H is low in a region close to the storage unit 11 in a fixed charge layer 14r, while a density of the positive fixed charges H is high in a region away from the storage unit 11 in the fixed charge layer 14r, with respect to the direction parallel to the second substrate surface 102. Therefore, the density of the accumulation charges e in the second substrate surface 102 becomes low in the region getting close to the storage unit 11, and becomes high in the region getting away from the storage unit 11, with respect to the direction parallel to the second substrate surface 102, so that the electric field is generated in that direction.

In this case, as shown by the thick solid line in FIG. 13, after being generated in the second substrate surface 102, the charge d making the dark current is likely to move so as to get away from the storage unit 11 due to the electric field generated with respect to the direction parallel to the second substrate surface 102, and then move toward the storage unit 11. Meanwhile, when the structure of this example is not used (the density of the accumulation charges e is uniform with respect to the direction parallel to the second substrate surface 102), as shown by the broken line in FIG. 13, after being generated in the second substrate surface 102, the charge d making the dark current is likely to directly move toward the storage unit 11.

As described above, when the structure of this example is used, the charge d making the dark current takes the longer route and the longer time to reach the storage unit 11, so that it is possible to improve the probability that the charge d disappears due to the recombination before the charge d reaches the storage unit 11.

In addition, similar to the above [4], in the structure of this example also, the charge d can preferably disappear by increasing the concentration of the p-type impurity in the substrate 10.

[6] In the above, the description has been given to the structure in which the positive accumulation charge is mainly accumulated in the second substrate surface 102 based on the negative fixed charge in the fixed charge layer (refer to FIGS. 2 to 8, and FIGS. 10 to 13), but in addition to (or instead of) that structure, an electrode layer may be provided above the fixed charge layer to apply a voltage thereto.

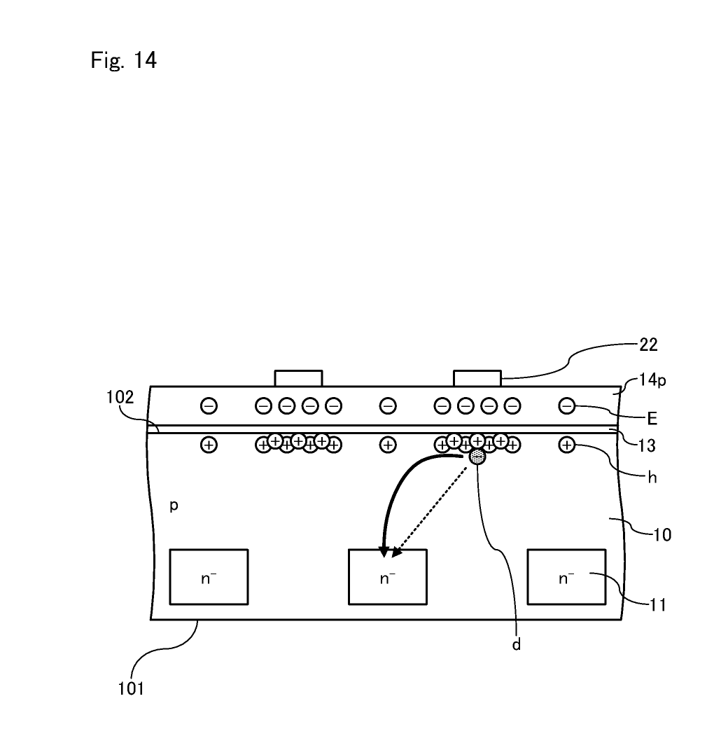

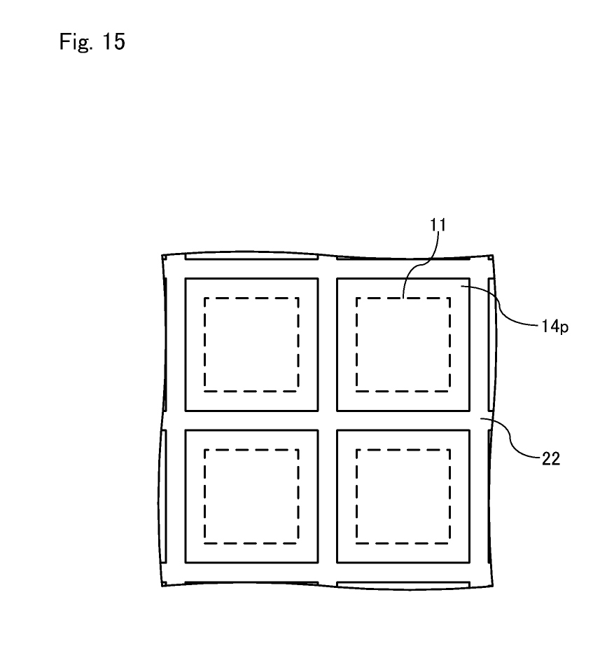

One example of a structure of the solid-state imaging element 1 in this case will be described with reference to FIGS. 14 and 15. FIG. 14 is an essential part cross-sectional view showing another example of the structure to reduce the dark current in the solid-state imaging element according to the embodiment of the present invention. In addition, FIG. 15 is a top view of a substrate to describe one example of a structure of the electrode layer. Furthermore, a thick solid-line arrow shown in FIG. 14 shows a route that the charge d making the dark current is likely to take without being recombined when the structure of this example is used. Meanwhile, a broken-line arrow shown in FIG. 14 shows a route that the charge d making the dark current is likely to take without being recombined when the structure of this example is not used. In addition, in order to specify the description, the description will be given to a structure in which an electrode layer 22 is provided in the structure described in the above [3] (refer to FIG. 11).

As shown in FIGS. 14 and 15, according to the structure of this example, the electrode layer 22 is provided above the region away from the storage unit 11, in the fixed charge layer 14p (region having a high density of the negative fixed charges E), with respect to the direction parallel to the second substrate surface 102. Furthermore, a voltage having the same (negative) polarity as that of the fixed charge E is applied to the electrode layer 22 at least while the charge (electron) generated by the photoelectric conversion is stored in the storage unit 11. Thus, compared to the structure described in the above [3] (refer to FIG. 11), the density of the accumulation charges h in the second substrate surface 102 becomes further low in the region getting close to the storage unit 11, and becomes further high in the region getting away from the storage unit 11, with respect to the direction parallel to the second substrate surface 102, so that a stronger electric field can be generated in that direction.

In this case, as shown by the thick solid line in FIG. 14, after being generated in the second substrate surface 102, the charge d making the dark current is likely to move so as to get close to the storage unit 11 due to the electric field generated with respect to the direction parallel to the second substrate surface 102, and then move toward the storage unit 11. Meanwhile, when the structure of this example is not used (the density of the accumulation charges h is uniform with respect to the direction parallel to the second substrate surface 102), as shown by the broken line in FIG. 14, after being generated in the second substrate surface 102, the charge d making the dark current is likely to directly move toward the storage unit 11.

As described above, when the structure of this example is used, the charge d making the dark current takes the longer route and the longer time to reach the storage unit 11, so that it is possible to improve the probability that the charge d disappears due to the recombination before the charge d reaches the storage unit 11.

In addition, in a case where the electrode layer 22 is composed of material which does not transmit the incident light to the substrate 10, it is preferable to provide the electrode layer 22 above the region away from the storage unit 11, in the fixed charge layer 14p, with respect to the direction parallel to the second substrate surface 102 as described above. However, in a case where the electrode layer 22 is composed of material which can transmit the incident light to the substrate 10, it can be arranged in any position on the fixed charge layer. That is, the structure of this example (structure having the electrode layer 22 above the fixed charge layer) can be applied to the structure in each of the above specific examples.

[7] In the above, the description has been given to the structure in which the storage unit 11 is arranged in the center of the pixel region A (refer to FIGS. 2 to 8, and FIGS. 10 to 15), but the storage unit 11 may be arranged in a region other than the center of the pixel region A, based on a positional relationship with an element such as a transistor provided on the wiring layer 12, for example.

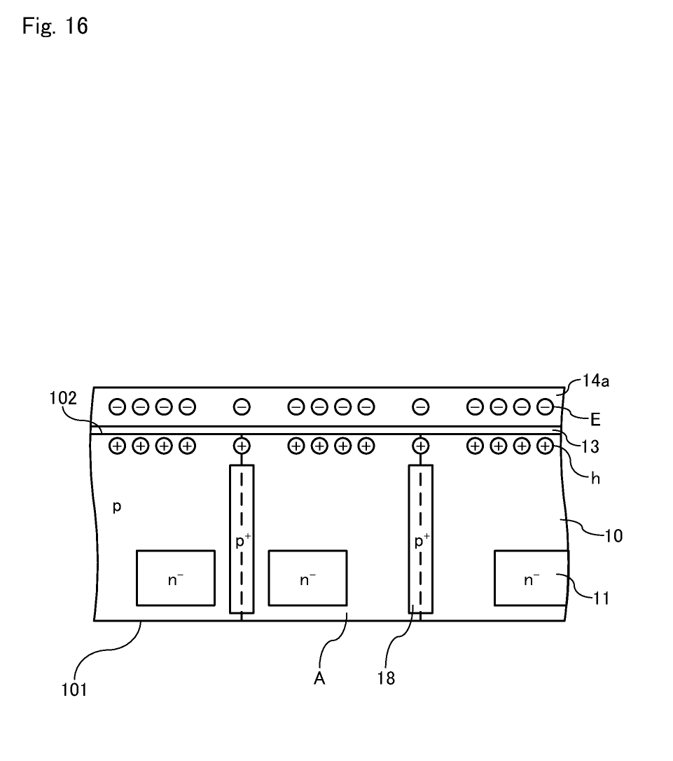

One example of a structure of the solid-state imaging element 1 in this case will be described with reference to FIG. 16. FIG. 16 is an essential part cross-sectional view showing another example of the structure to reduce the dark current in the solid-state imaging element according to the embodiment of the present invention. In addition, in order to specify the description, the description will be given to the structure of another example corresponding to the structure of the above first specific example (refer to FIG. 2).

As shown in FIG. 16, according to the structure of this example, the storage unit 11 is arranged so as to get close to the separation unit 18 from the center of the pixel region A. More specifically, the storage units 11 are arranged with periodicity with respect to a certain direction parallel to the second substrate surface 102 in such a manner that the separation unit 18 around which the adjacent storage units 11 are close to each other, and the separation unit 18 around which the adjacent storage units 11 are away from each other are alternately repeated.

According to the structure in this example, the density of the accumulation charges h becomes high in a region getting close to the center of the pixel region A (getting away from the separation unit 18), and becomes low in a region getting close to an end of the pixel region A (getting close to the separation unit 18), with respect to the direction parallel to the second substrate surface 102, which is the same as that of the above first specific example (refer to FIG. 2). That is, according to the structure of this example, the density of the accumulation charges h varies based on the arrangement of the pixel regions A (or the separation units 18).

In this structure also, the electric field is generated with respect to the direction parallel to the second substrate surface 102 based on the distribution of the density of the accumulation charges h, so that the charge making the dark current takes the longer route and the longer time to reach the storage unit 11. As a result, it is possible to improve the probability that the charge disappears due to recombination before reaching the storage unit 11, and the dark current can be reduced.

Furthermore, the density of the accumulation charges h may vary based on the arrangement of the storage units 11 without varying based on the arrangement of the pixel regions A (or separation units 18). More specifically, in the structure shown in FIG. 16, the density of the accumulation charges h may become high in the region getting close to the storage unit 11 (just above the storage unit 11), and become low in the region getting away from the storage unit 11 (between the regions just above the storage units 11), with respect to the direction parallel to the second substrate surface 102.

[8] When the fixed charge layer is composed of hafnium oxide, for example, its refractive index can be higher than that of a material (such as silicon oxide) composing the other layer. In this case, the fixed charge layer can be used as an inner lens, so that the colors can be prevented from being mixed, which is preferable. However, when a difference in refractive index becomes large between the fixed charge layer and the adjacent other layer, the light is reflected on the fixed charge layer before it is inputted to the substrate 10, which could reduce sensitivity of the solid-state imaging element.

Thus, it is preferable to prevent the reflection by adjusting a film thickness of the fixed charge layer. For example, it is preferable to adjust the film thickness of the fixed charge layer so that as for a green light having a middle wavelength (such as 500 nm or more and 560 nm or less) among lights passing through the color filter, the green light can be prevented from being reflected.

More specifically, it is preferable to adjust the film thickness of the fixed charge layer so that a film thickness in the center of the region just above the storage unit 11 satisfies the following formula (1). In addition, in the following formula (1), N represents a refractive index of the fixed charge layer, and K is an integer more than 0. In addition, the reflection can be sufficiently prevented as long as the film thickness of the fixed charge layer is within a predetermined range from a film thickness with which the light reflection is a minimum. Therefore, as for the following formula (1), it is allowed that the film thickness of the fixed charge layer falls within the above range (such as ±25%).

0.75×{500/(4×N)+K×500/(2×N)} nm or more, and

1.25×{560/(4×N)+K×560/(2×N)} nm or less (1)

The color filter transmits red and blue lights other than green light. Therefore, it is more preferable to adjust the film thickness of the fixed charge layer so that reflection of the red and blue lights can be also prevented. In addition, as the film thickness of the fixed charge layer increases, light absorption increases in the fixed charge layer. Therefore, it is further preferable to thin the film thickness of the fixed charge layer as much as possible.

[9] The fixed charge layer is provided only on the second substrate surface 102 of the substrate 10 in the structure in each of the above-described examples (refer to FIGS. 1 to 16), but the fixed charge layer may be provided only on the first substrate surface 101 of the substrate 10, or may be provided on each of the first substrate surface 101 and the second substrate surface 102.
[10] The conductivity type of the semiconductor and the polarity of the charge in the solid-state imaging element 1 may be opposite to those in the structure in each of the above-described examples (refer to FIGS. 1 to 13). More specifically, the substrate 10 may be formed of the n-type semiconductor, and the storage unit 11 may be formed of the p-type semiconductor and store holes generated by photoelectric conversion.

### INDUSTRIAL APPLICABILITY

The solid-state imaging element according to the present invention can be preferably used as a CMOS imaging sensor or CCD imaging sensor mounted on various kinds of electronic devices each having an imaging function.

### EXPLANATION OF REFERENCES

1 Solid-state imaging element
10 Substrate
101 First substrate surface
102 Second substrate surface
11 Storage unit
12 Wiring layer
13, 13e Base layer
14, 14a to 14g, 14p to 14r Fixed charge layer
15 Insulating layer
16 Color filter
17 On-chip lens
18 Separation unit
19 Barrier unit
20 Attraction unit
21 Light-blocking layer
22 Electrode layer
A Pixel region
E, H Fixed charge
c, d, e, h Charge
R1, R2 Resist

1. A solid-state imaging element comprising:
a substrate formed of semiconductor and having a plurality of pixel regions;
a storage unit arranged in the substrate with respect to each of the pixel regions, formed of semiconductor having a conductivity type opposite to the substrate, and configured to store a charge having a first polarity and generated by photoelectric conversion; and
a fixed charge layer provided above at least one substrate surface and having a first fixed charge, wherein
a density of accumulation charges provided in the substrate surface and having a polarity opposite to the first fixed charge varies based on an arrangement of the pixel regions or an arrangement of the storage unit, with respect to a direction parallel to the substrate surface,
the density of the accumulation charges in the substrate surface becomes low in a region getting close to the storage unit, and becomes high in a region getting away from the storage unit, with respect to the direction parallel to the substrate surface.

2. The solid-state imaging element according to claim 1, wherein
a polarity of the first fixed charge is the first polarity, and a polarity of the accumulation charge is a second polarity opposite to the first polarity.

3-4. (canceled)

5. The solid-state imaging element according to claim 1, wherein
a density of the first fixed charges in a region close to the storage unit in the fixed charge layer is different from a density of the first fixed charges in a region away from the storage unit in the fixed charge layer, with respect to the direction parallel to the substrate surface.

6. The solid-state imaging element according to claim 5, wherein
a heat treatment method performed for the region close to the storage unit in the fixed charge layer is different from a heat treatment method performed for the region away from the storage unit in the fixed charge layer, with respect to the direction parallel to the substrate surface.

7. The solid-state imaging element according to claim 5, wherein
an additive condition of an impurity in the region close to the storage unit in the fixed charge layer is different from an additive condition of the impurity in the region away from the storage unit in the fixed charge layer, with respect to the direction parallel to the substrate surface.

8. The solid-state imaging element according to claim 1, wherein
a film thickness of the region close to the storage unit in the fixed charge layer is different from a film thickness of the region away from the storage unit in the fixed charge layer, with respect to the direction parallel to the substrate surface.

9. The solid-state imaging element according to claim 1, wherein
a material of at least one part in the region close to the storage unit in the fixed charge layer is different from a material of at least one part in the region away from the storage unit in the fixed charge layer, with respect to the direction parallel to the substrate surface.

10. The solid-state imaging element according to claim 1, wherein
one of the region close to the storage unit in the fixed charge layer and the region away from the storage unit in the fixed charge layer, with respect to the direction parallel to the substrate surface has a second fixed charge having the second polarity.

11. The solid-state imaging element according to claim 1, wherein
a distance between the region close to the storage unit in the fixed charge layer and the substrate surface is different from a distance between the region away from the storage unit in the fixed charge layer and the substrate surface, with respect to the direction parallel to the substrate surface.

12. The solid-state imaging element according to claim 11, further comprising:
a base layer formed of insulator and provided between the substrate surface and the fixed charge layer, wherein
a film thickness of a region close to the storage unit in the base layer is different from a film thickness of a region away from the storage unit in the base layer, with respect to the direction parallel to the substrate surface.

13. The solid-state imaging element according to claim 1, wherein
a barrier unit having a higher impurity concentration than a surrounding area is formed in a region away from the storage unit in the substrate, with respect to the direction parallel to the substrate surface.

14. The solid-state imaging element according to claim 13, wherein
an attraction unit is formed of semiconductor having the conductivity type opposite to the substrate, in the barrier unit beside the substrate surface.

15. The solid-state imaging element according to claim 1, further comprising:
an electrode layer provided in one of a region close to the storage unit above the fixed charge layer, and a region away from the storage unit above the fixed charge layer, with respect to the direction parallel to the substrate surface, wherein
a voltage having the same polarity as the first fixed charge is applied to the electrode layer at least while the charge having the first polarity is stored in the storage unit.

16. The solid-state imaging element according to claim 1, wherein
a separation unit having a higher impurity concentration than a surrounding area is formed in a boundary between the pixel regions in the substrate.

17. The solid-state imaging element according to claim 1, further comprising:
a wiring layer provided on the substrate beside a first substrate surface, for controlling the charge having the first polarity and stored in the storage unit, wherein
light enters the substrate through a second substrate surface opposite to the first substrate surface, and the charge having the first polarity and generated by the photoelectric conversion of the light is stored in the storage unit, and
the fixed charge layer is provided above at least the second substrate surface.

18. The solid-state imaging element according to claim 1, wherein
the fixed charge layer comprises at least one of hafnium oxide, aluminum oxide, zirconium oxide, tantalum oxide, titanium oxide, tungsten oxide, zinc oxide, yttrium oxide, oxide of lanthanoid, silicon oxide, nickel oxide, cobalt oxide, and copper oxide.

19. The solid-state imaging element according to claim 1, wherein
a film thickness in a center of a region immediately above the storage unit in the fixed charge layer is
0.75×{500/(4×N)+K×500/(2×N)} nm or more, and
1.25×{560/(4×N)+K×560/(2×N)} nm or less,
when N represents a refractive index of the fixed charge layer, and K represents an integer of 0 or more.

20. The solid-state imaging element according to claim 1, wherein a polarity of the first fixed charge is a second polarity opposite to the first polarity, and a polarity of the accumulation charge is the first polarity.
